(19) United States
(12) Patent Application Publication
(10) Pub. No.: US 2009/0277387 A1
(43) Pub. Date: Nov. 12, 2009

(54) SUSCEPTOR AND CHEMICAL VAPOR DEPOSITION APPARATUS INCLUDING THE SAME

(75) Inventors: Ho Il JUNG, Suwon (KR); Sang Duk Yoo, Seongnam (KR); Won Shin Lee, Seoul (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO., LTD

(21) Appl. No.: 12/253,514

(22) Filed: Oct. 17, 2008

(30) Foreign Application Priority Data
May 6, 2008 (KR) 10-2008-0042053

(51) Int. Cl. C23C 16/54

(52) U.S. Cl. 118/725

(57) ABSTRACT

There are provided a susceptor and a chemical vapor deposition apparatus including the same. The susceptor includes: at least one pocket accommodating a deposition object therein; a seating part stepped downward from a top end of the pocket, the seating part having the deposition object placed thereon; and a recess recessed from the seating part to a predetermined depth, wherein the recess has a radius of curvature ranging from substantially 8000 mm to 25000 mm.

### CROSS-REFERENCE TO RELATED APPLICATIONS

This application claims the priority of Korean Patent Application No. 2008-42053 filed on May 6, 2008, in the Korean Intellectual Property Office, the disclosure of which is incorporated herein by reference.

### BACKGROUND OF THE INVENTION

1. Field of the Invention

The present invention relates to a susceptor and a chemical vapor deposition apparatus including the same, and more particularly, to a susceptor utilized in a metal organic chemical vapor deposition (MOCVD) apparatus, and a chemical vapor deposition apparatus including the same.

2. Description of the Related Art

In general, a metal organic chemical vapor deposition (MOCVD) apparatus forms a metal oxide film on a wafer substrate by chemical reaction. With this apparatus, an organic compound vapor of a metal with high vapor pressure is fed into a substrate heated inside a vacuum chamber to grow a metal film on the substrate.

FIG. 1 schematically illustrates a conventional chemical vapor deposition apparatus. As shown in FIG. 1, the conventional chemical vapor deposition apparatus includes a chamber 10 defining a predetermined vacuum space, a susceptor 20 disposed inside the chamber 10 to accommodate a substrate 30 and a radio frequency (RF) coil 40 disposed adjacent to the susceptor 20.

A gas intake part 11 is provided at each of edges of the chamber 10 to supply a material gas for forming a thin film. A gas outlet opening 12 is provided in a center of the chamber 10 to allow a gas fed through the gas intake part 11 to flow inside the chamber 10 and be exhausted.

Therefore, the substrate 30 placed on the susceptor 20 is exposed to the flowing gas fed through the gas intake part 11. Also, the RF coil 40 is induction-heated to apply a heat to the substrate 30, thereby allowing a thin film to be grown on the substrate 30.

As described above, when the thin film is grown on the substrate 30, very high temperature heat is generated from the RF coil 40, causing edges of the substrate 30 to be warped upward, that is, to suffer a bowing effect.

However, as shown in FIG. 1, the conventional susceptor 20 is flat on a bottom surface where the substrate 30 is placed. Thus, in a case where the substrate 30 is warped due to high temperature during a process of growing the thin film on the substrate 30, a central portion and edge portions of the substrate are heated with different temperatures. This causes a temperature of the substrate to be non-uniform overall, accordingly leading to a non-uniform growth of the thin film on the substrate overall.

FIG. 2 illustrates temperature uniformity of a substrate in a susceptor of a conventional chemical vapor deposition apparatus.

FIG. 2 plots temperature uniformity of the substrate when deposition is performed in a conventional susceptor having a flat bottom surface, Here, the experimental results are obtained by analyzing and measuring a wavelength of emission light with respect to stimulus light using a photoluminescence apparatus.

As shown in FIG. 2, the substrate, when deposited, suffers warping and thus the wavelength of the emission light is shortest around a center of the substrate and longer toward edges.

Also, the emission light is not uniform in wavelength overall and has a standard deviation of about 5.8 nm. This results in a non-uniform temperature of the substrate when the substrate is deposited, and degrades uniformity of the grown thin film.

As methods for enhancing temperature uniformity and uniform growth of the thin film, a susceptor may be rotated, substrates each may be revolved and an RF coil may be removed to control temperature. However, in a case where the thin film grows fast, these methods are limited in improving temperature uniformity.

### SUMMARY OF THE INVENTION

An aspect of the present invention provides a susceptor in which a deposition object is increased in temperature uniformity when a thin film is grown on the deposition object at a high temperature to allow the thin film to grow uniformly overall, thereby ensuring more reliable quality of finished goods, and a chemical deposition apparatus including the same.

According to an aspect of the present invention, there is provided a susceptor including: at least one pocket accommodating a deposition object therein; a seating part stepped downward from a top end of the pocket, the seating part having the deposition object placed thereon; and a recess recessed from the seating part to a predetermined depth, wherein the recess has a radius of curvature ranging from substantially 8000 mm to 25000 mm.

The seating part may have an outer circumferential diameter ranging from substantially 2 to 12 inches, and the recess has the radius of curvature ranging from substantially 8000 mm to 25000 mm.

The recess may have an outer circumferential diameter ranging from substantially 2 to 12 inches, and a perpendicular depth from the seating part to a bottom end of the recess satisfies following Equation;

ro1*{1-cos(sin⁻¹(D/(2*ro1)))}≦t≦ro2*{1-cos(sin⁻¹(D/(2*ro2)))} Equation,

where ro1 and ro2 are radiuses of curvature of the recess, and ro1 is substantially 25000 mm and ro2 is substantially 8000 mm.

The seating part may have an outer circumferential diameter ranging from substantially 2 to 12 inches, and an angle between a center of the recess and an outer circumference of the seating part with respect to a center of curvature of the recess substantially satisfies following Equation;

sin⁻¹(D/(2*ro1))≦θ≦sin⁻¹(D/(2*ro2)) Equation,

where ro1 and ro2 are radiuses of curvature of the recess, and ro1 is substantially 25000 mm and ro2 substantially 8000 mm.

According to another aspect of the present invention, there is provided a chemical vapor deposition apparatus including the susceptor described above.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 schematically illustrates a structure of a susceptor in a conventional chemical vapor deposition apparatus;

FIG. 2 illustrates temperature uniformity of a substrate which is deposited in the susceptor of the chemical vapor deposition apparatus shown in FIG. 1;

FIG. 3 schematically illustrates a structure of a susceptor according to an exemplary embodiment of the invention;

FIG. 4 illustrates various parameters in the susceptor shown in FIG. 3;

FIG. 5 illustrates results obtained when a recess has a depth of 50 μm;

FIG. 6 illustrates results obtained when a recess has a depth of 25 μm; and

FIG. 7 is a graph illustrating results based on data shown in Tables 1 to 8.

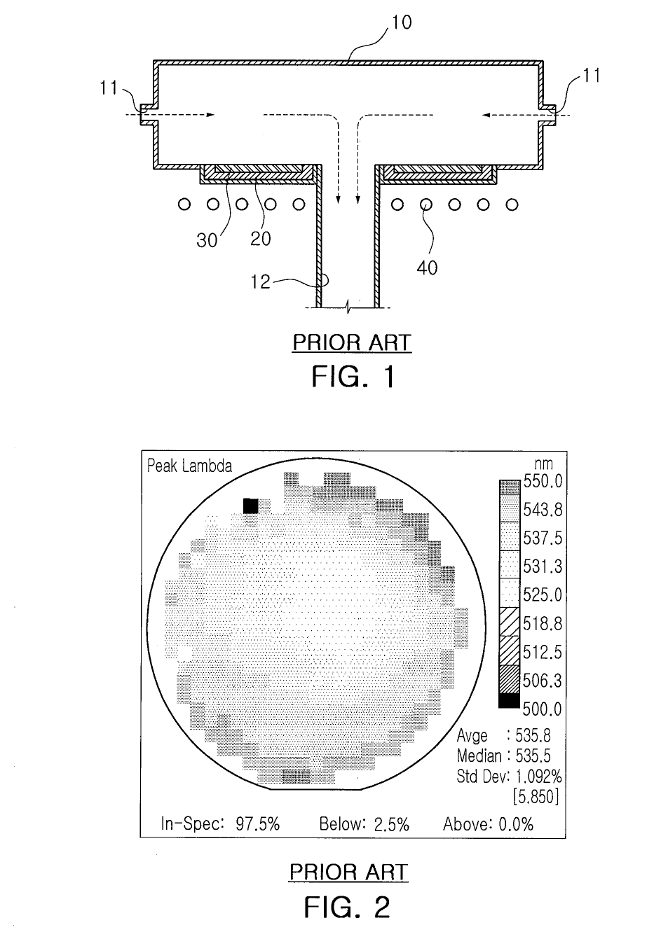

### DETAILED DESCRIPTION OF THE PREFERRED EMBODIMENT

Exemplary embodiments of the present invention will now be described in detail with reference to the accompanying drawings.

In the specification, a chemical vapor deposition apparatus according to the present invention includes all kinds of chemical vapor deposition apparatuses including a susceptor of the present invention. Parts other than the susceptor are substantially identical to those of a conventional apparatus and thus will not be described in further detail. Hereinafter, description will be chiefly given of the susceptor according to the present invention.

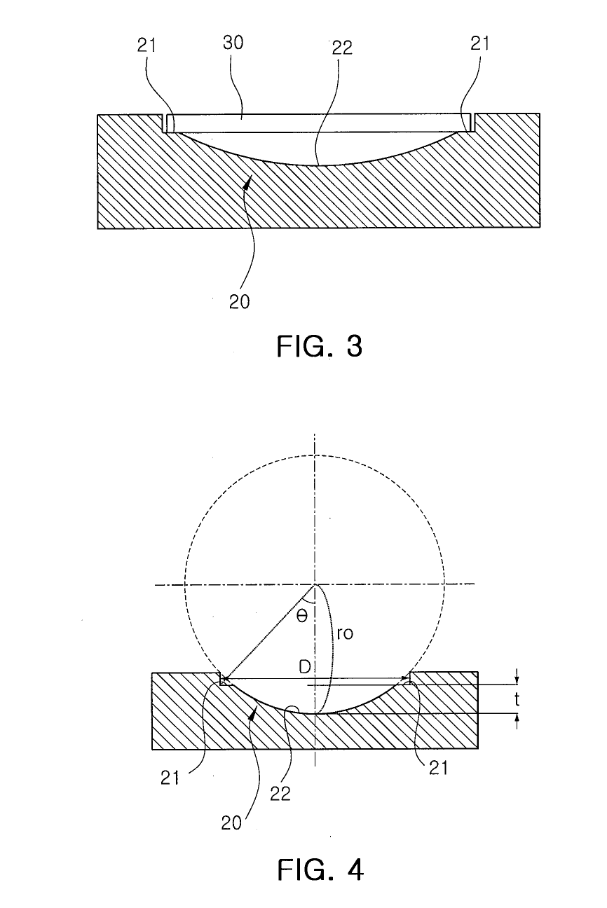

First, a susceptor will be schematically described according to an exemplary embodiment of the invention with reference to FIG. 3.

As shown in FIG. 3, the susceptor of the present embodiment includes a pocket 20 accommodating a deposition object 30.

The pocket of the susceptor of the present embodiment is provided in singularity to accommodate one deposition object. However, the pocket of the present embodiment is not limited to a singular one and at least two pockets may be provided to accommodate at least two deposition objects.

As shown in FIG. 3, the pocket 20 of the present embodiment includes a seating part 21 and a recess 22.

The seating part 21 is stepped downward from an upper end of the pocket 20. The seating part 21 is provided to seat the deposition object 30 thereon. The seating part 21 may be formed around the pocket 20.

The recess 22 is recessed downward from the seating part 21 to have a predetermined radius of curvature and a predetermined depth.

Therefore, even though the deposition object is warped when a thin film is grown on the deposition object in a high temperature atmosphere, heat can be transferred uniformly from a center of the deposition object to edges thereof. This increases uniformity of the temperature and subsequently uniformity of the thin film.

Meanwhile, FIG. 4 illustrates a diameter D of the pocket 20 of the susceptor, a radius of curvature ro of the recess 22, a perpendicular depth t from the seating part 21 to a bottom end of the recess 22, and an angle θ between an outer circumference of the seating part 21 and a center of the recess 22 with respect to a center of curvature of the recess 22.

The diameter D of the pocket 20 specifically denotes an outer circumferential diameter of the seating part 21.

The pocket 20 may be varied in diameter D. That is, the diameter of the pocket 20 may range from 2 to 12 inches.

In the pocket whose diameter can be varied, the radius of curvature or depth of the recess 22 may be determined by predetermined conditions.

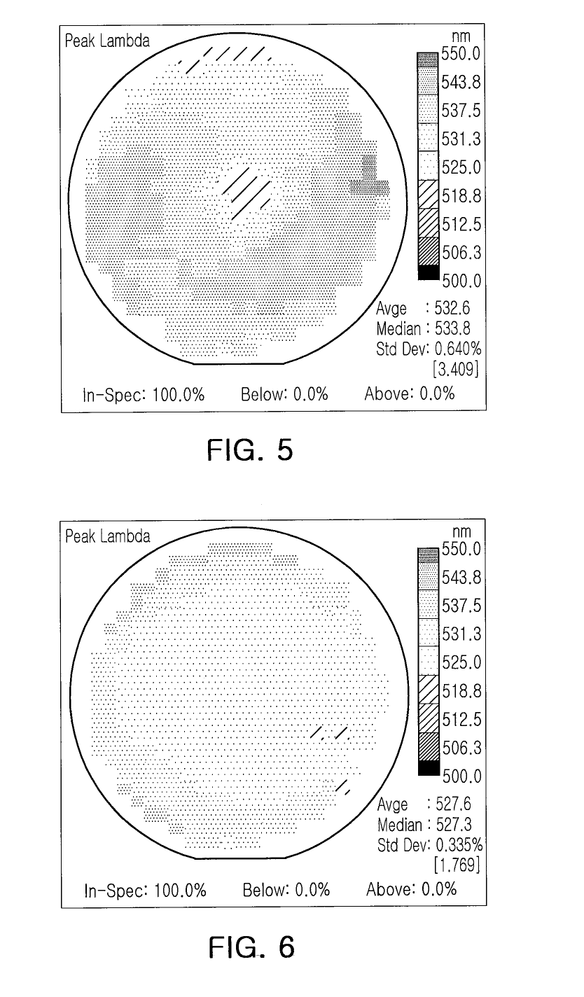

FIG. 5 plots analysis results of temperature uniformity of the deposition object which are obtained by measuring a change in wavelength of emission light with respect to stimulus light using a photoluminescence apparatus. Here, the pocket has a diameter of 2 inches and the recess has a depth of 50 μm.

Based on the experimental results, the deposition object of the susceptor of FIG. 5 exhibits much better temperature uniformity than the deposition object of the conventional susceptor shown in FIG. 2. In the experimental results shown in FIG. 5, the wavelength has a standard deviation of 3.4 nm, which is a great improvement over the conventional art.

FIG. 6 plots experimental results of temperature uniformity which are obtained when the pocket has a diameter of 2 inches and the recess has a depth of 25 μm.

Referring to FIG. 6, the wavelength of emission light has a standard deviation of 1.8 nm, and thus the susceptor is improved in temperature uniformity over the conventional susceptor shown in FIG. 2 and the susceptor of FIG. 5 having the recess with a depth of 50 μm.

Therefore, in the pocket with a diameter of 2 inches, the recess has a depth in an adequate range from 0 to 50 μm.

To ensure the satisfying temperature uniformity, the recess has a depth ranging from about 12 μm to about 40 μm when the pocket has a depth of 2 inches.

Here, the recess has a depth in the above range when the pocket has a diameter of 2 inches. With an increase in the diameter of the pocket, the recess has a depth varied according to a radius of curvature identical to a radius of curvature when the diameter is 2 inches.

That is, as the pocket is varied in diameter, the recess has a depth varied to ensure satisfying results. However, the radius of curvature of the recess is substantially identically applied even when the diameter of the pocket is varied.

Therefore, the radius of curvature of the recess having a depth in the above range can be obtained and applied identically to the pocket having a greater diameter. Accordingly, the depth range of the recess can be obtained when the pocket is varied in diameter.

In order to obtain an effective radius of curvature of the recess as described above, the following Equation relating to the diameter D, radius of curvature ro, angle θ, and depth t of the recess can be derived with reference to FIG. 4.

θ=sin−1(D/(2*ro)) Equation 1,

Also, the following Equation can be derived.

t=ro*{1-cos(sin−1(D/(2*ro))} Equation 2,

Accordingly, a depth range of the recess, i.e., 12 μm and 40 μm selected when the pocket has a diameter of 2 inches can be applied to the Equation 2 to obtain the radius of curvature ro. That is, the radius of curvature in the following range can be applied to the pockets with various diameters.

8000 mm≦ro≦25000 mm

The radius of curvature derived as described above is applied to a case where the pocket has a diameter of 2 to 12 inches to determine the θ value to be in the range according to the following Equation 3.

sin⁻¹(D/(2*ro1))≦θ≦sin⁻¹(D/(2*ro2)) Equation 3,

where ro1 and ro2 are the radiuses of curvature of the recess. ro1 is substantially 25000 mm and ro2 is substantially 8000 mm.

Moreover, in a case where the pocket has a diameter set to a value in the range of 2 to 12 inches, the recess has a depth t determined to be in the range according to following Equation 4;

ro1*{1-cos(sin⁻(D/(2*ro1)))}≦t≦ro2*{1-cos(sin⁻¹(D/(2*ro2)))} Equation 4,

where ro1 and ro2 are the radiuses of curvature of the recess. ro1 is substantially 25000 mm and ro2 is substantially 8000 mm.

Following Tables 1 to 8 show results obtained when detailed numerical values are applied to Equation 4.

In each of the Tables, inch denotes a diameter of the pocket indicated with the unit of inch, D (mm) denotes a diameter of the pocket indicated with the unit of mm, θ (rad) denotes an angle from a center of curvature indicated with the unit of radian and t (mm) denotes a depth of the recess indicated with the unit of mm.

TABLE 1

| Inch | D (mm) | Θ (rad) | t (mm) |
|---|---|---|---|
| 2 | 50.8 | 0.003175 | 0.040323 |
| 3 | 76.2 | 0.004763 | 9.090726 |
| 4 | 101.6 | 0.00635 | 0.161292 |
| 5 | 127 | 0.007938 | 0.25202 |
| 6 | 152.4 | 0.009525 | 0.362911 |
| 7 | 177.8 | 0.011113 | 0.493966 |
| 8 | 203.2 | 0.0127 | 0.645186 |
| 9 | 228.6 | 0.014288 | 0.816572 |
| 10 | 254 | 0.015876 | 1.008126 |
| 11 | 279.4 | 0.017463 | 1.219849 |
| 12 | 304.8 | 0.019051 | 1.451742 |

The data shown in Table 1 above are obtained when the recess has a radius of curvature (ro) of 8000 mm.

TABLE 2

| Inch | D (mm) | Θ (rad) | t (mm) |
|---|---|---|---|
| 2 | 50.8 | 0.00254 | 0.032258 |
| 3 | 76.2 | 0.00381 | 0.072581 |
| 4 | 101.6 | 0.00508 | 0.129033 |
| 5 | 127 | 0.00635 | 0.201615 |
| 6 | 152.4 | 0.00762 | 0.290326 |
| 7 | 177.8 | 0.00889 | 0.395168 |
| 8 | 203.2 | 0.01016 | 0.516141 |
| 9 | 228.6 | 0.01143 | 0.653246 |
| 10 | 254 | 0.0127 | 0.806483 |
| 11 | 279.4 | 0.01397 | 0.975852 |
| 12 | 304.8 | 0.015241 | 1.161355 |

The data shown in Table 2 above are obtained when the recess has a radius of curvature (ro) of 10000 mm.

TABLE 3

| Inch | D (mm) | Θ (rad) | t (mm) |
|---|---|---|---|
| 2 | 50.8 | 0.002117 | 0.026882 |
| 3 | 76.2 | 0.003175 | 0.060484 |
| 4 | 101.6 | 0.004233 | 0.107527 |
| 5 | 127 | 0.005292 | 0.168012 |
| 6 | 152.4 | 0.00635 | 0.241937 |
| 7 | 177.8 | 0.007408 | 0.329305 |
| 8 | 203.2 | 0.008467 | 0.430114 |
| 9 | 228.6 | 0.009525 | 0.544366 |
| 10 | 254 | 0.010584 | 0.67206 |
| 11 | 279.4 | 0.011642 | 0.813198 |
| 12 | 304.8 | 0.0127 | 0.967779 |

The data shown in Table 3 above are obtained when the recess has a radius of curvature (ro) of 12000 mm.

TABLE 4

| Inch | D (mm) | Θ (rad) | t (mm) |
|---|---|---|---|
| 2 | 50.8 | 0.001814 | 0.023041 |
| 3 | 76.2 | 0.002721 | 0.051843 |
| 4 | 101.6 | 0.003629 | 0.092166 |
| 5 | 127 | 0.004536 | 0.14401 |
| 6 | 152.4 | 0.005443 | 0.207374 |
| 7 | 177.8 | 0.00635 | 0.28226 |
| 8 | 203.2 | 0.007257 | 0.368668 |
| 9 | 228.6 | 0.008164 | 0.466597 |
| 10 | 254 | 0.009072 | 0.576048 |
| 11 | 279.4 | 0.009979 | 0.697021 |
| 12 | 304.8 | 0.010886 | 0.829516 |

The data shown in Table 4 above are obtained when the recess has a radius of curvature (ro) of 14000 mm.

TABLE 5

| Inch | D (mm) | Θ (rad) | t (mm) |
|---|---|---|---|
| 2 | 50.8 | 0.001337 | 0.016978 |
| 3 | 76.2 | 0.002005 | 0.0382 |
| 4 | 101.6 | 0.002674 | 0.067912 |
| 5 | 127 | 0.003342 | 0.106112 |
| 6 | 152.4 | 0.004011 | 0.152802 |
| 7 | 177.8 | 0.004679 | 0.20798 |
| 8 | 203.2 | 0.005347 | 0.271648 |
| 9 | 228.6 | 0.006016 | 0.343805 |
| 10 | 254 | 0.006684 | 0.424452 |
| 11 | 279.4 | 0.007353 | 0.513588 |
| 12 | 304.8 | 0.008021 | 0.611214 |

The data shown in Table 5 above are obtained when the recess has a radius of curvature (ro) of 19000 mm.

TABLE 6

| Inch | D (mm) | Θ (rad) | t (mm) |
|---|---|---|---|
| 2 | 50.8 | 0.00121 | 0.015361 |
| 3 | 76.2 | 0.001814 | 0.034562 |
| 4 | 101.6 | 0.002419 | 0.061444 |
| 5 | 127 | 0.003024 | 0.096006 |
| 6 | 152.4 | 0.003629 | 0.138249 |
| 7 | 177.8 | 0.004233 | 0.188173 |
| 8 | 203.2 | 0.004838 | 0.245777 |
| 9 | 228.6 | 0.005443 | 0.311062 |
| 10 | 254 | 0.006048 | 0.384027 |
| 11 | 279.4 | 0.006652 | 0.464674 |
| 12 | 304.8 | 0.007257 | 0.553002 |

The data shown in Table 6 above are obtained when the recess has a radius of curvature (ro) of 21000 mm.

TABLE 7

| Inch | D (mm) | Θ (rad) | t (mm) |
|---|---|---|---|
| 2 | 50.8 | 0.001104 | 0.014025 |
| 3 | 76.2 | 0.001657 | 0.031557 |
| 4 | 101.6 | 0.002209 | 0.056101 |
| 5 | 127 | 0.002761 | 0.087658 |
| 6 | 152.4 | 0.003313 | 0.126227 |
| 7 | 177.8 | 0.003865 | 0.17181 |
| 8 | 203.2 | 0.004417 | 0.224405 |
| 9 | 228.6 | 0.00497 | 0.284012 |
| 10 | 254 | 0.005522 | 0.350633 |
| 11 | 279.4 | 0.006074 | 0.424267 |
| 12 | 304.8 | 0.006626 | 0.504913 |

The data shown in Table 7 above are obtained when the recess has a radius of curvature (ro) of 23000 mm.

TABLE 8

| Inch | D (mm) | Θ (rad) | t (mm) |
|---|---|---|---|
| 2 | 50.8 | 0.001016 | 0.012903 |
| 3 | 76.2 | 0.001524 | 0.029032 |
| 4 | 101.6 | 0.002032 | 0.051613 |
| 5 | 127 | 0.00254 | 0.080645 |
| 6 | 152.4 | 0.003048 | 0.116129 |
| 7 | 177.8 | 0.003556 | 0.158065 |
| 8 | 203.2 | 0.004064 | 0.206452 |
| 9 | 228.6 | 0.004572 | 0.261291 |
| 10 | 254 | 0.00508 | 0.322582 |
| 11 | 279.4 | 0.005588 | 0.390325 |
| 12 | 304.8 | 0.006096 | 0.46452 |

The data shown in Table 8 are obtained when the recess has a radius of curvature (ro) of 25000 mm.

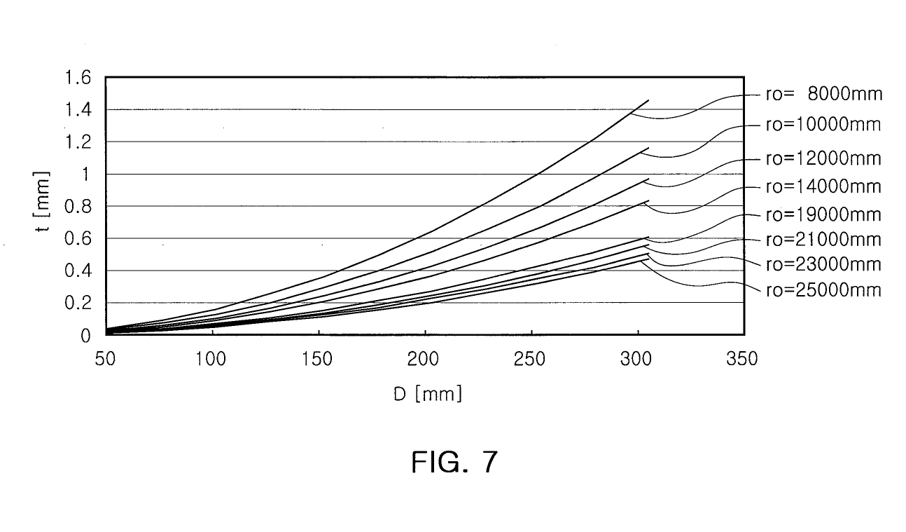

Also, a graph of FIG. 7 is plotted based on the data shown in Tables 1 to 8 above.

Through the graph of FIG. 7, whatever value the diameter has when the radius of curvature ro ranges from 8000 mm to 25000 mm, the recess can have a depth in an adequate range.

Therefore, when the pocket has a diameter set to any value in the range of about 2 to 12 inches or about 50 mm to 310 mm, the recess has a depth appropriately determined according to the graph of FIG. 7. This allows for a more uniform temperature of the deposition object and more uniform growth of the thin film during a deposition process.

As set forth above, according to exemplary embodiments of the invention, in a susceptor and a chemical vapor deposition apparatus including the same, a pocket accommodating a deposition object has a structure changed according to a predetermined condition. This increases temperature uniformity of the deposition object during a process of growing a thin film and ensures the thin film to be grown uniformly.

While the present invention has been shown and described in connection with the exemplary embodiments, it will be apparent to those skilled in the art that modifications and variations can be made without departing from the spirit and scope of the invention as defined by the appended claims.

What is claimed is:

1. A susceptor comprising:
at least one pocket accommodating a deposition object therein;
a seating part stepped downward from a top end of the pocket, the seating part having the deposition object placed thereon; and
a recess recessed from the seating part to a predetermined depth,
wherein the recess has a radius of curvature ranging from substantially 8000 mm to 25000 mm.

2. The susceptor of claim 1, wherein the seating part has an outer circumferential diameter ranging from substantially 2 to 12 inches, and the recess has the radius of curvature ranging from substantially 8000 mm to 25000 mm.

3. The susceptor of claim 1, wherein the recess has an outer circumferential diameter ranging from substantially 2 to 12 inches, and a perpendicular depth from the seating part to a bottom end of the recess satisfies following Equation;
ro1*{1-cos(sin⁻¹(D/(2*ro1)))}≦t≦ro2*{1-cos(sin⁻¹(D/(2*ro2)))} Equation,
where ro1 and ro2 are radiuses of curvature of the recess, and ro1 is substantially 25000 mm and ro2 is substantially 8000 mm.

4. The susceptor of claim 1, wherein the seating part has an outer circumferential diameter ranging from substantially 2 to 12 inches, and an angle between a center of the recess and an outer circumference of the seating part with respect to a center of curvature of the recess substantially satisfies following Equation;
sin⁻¹(D/(2*ro1))≦θ≦sin⁻¹(D/(2*ro2)) Equation,
where ro1 and ro2 are radiuses of curvature of the recess, and ro1 is substantially 25000 mm and ro2 substantially 8000 mm.

5. A chemical vapor deposition apparatus comprising the susceptor defined of claim 1.
